(19) United States
(12) Patent Application Publication
(10) Pub. No.: US 2011/0259879 A1
(43) Pub. Date: Oct. 27, 2011

(54) Multi-Zone Induction Heating for Improved Temperature Uniformity in MOCVD and HVPE Chambers

(75) Inventors: Hiroji Hanawa, Sunnyvale, CA (US); Kyawwin Jason Maung, Daly City, CA (US); Karl Brown, San Jose, CA (US)

(73) Assignee: APPLIED MATERIALS, INC., Santa Clara, CA (US)

(21) Appl. No.: 13/092,800

(22) Filed: Apr. 22, 2011

Related U.S. Application Data
(60) Provisional application No. 61/326,814, filed on Apr. 22, 2010.

(51) Int. Cl. H05B 6/10; C23C 16/458; C30B 35/00; C23C 16/46

(52) U.S. Cl. 219/634; 118/725; 219/647

(57) ABSTRACT

Embodiments of the invention generally relate to apparatuses and methods for utilizing a plurality of induction heat sources to uniformly heat a plurality of substrates within a processing chamber. By utilizing multiple heating zones that are each separately powered, the temperature distribution across the susceptor, over which the substrates rotate, may be uniform. The heat sources may be disposed outside of the processing chamber. In one embodiment, a processing chamber is provided which includes a susceptor disposed adjacent a first side of a window, a substrate carrier coupled with the susceptor, an inner inductive heating element disposed adjacent a second side of the window opposite the first side, an outer inductive heating element separate from and encompassing the inner inductive heating element and disposed adjacent to the second side of the window, and a parasitic load ring positioned below the outer inductive heating element.

### CROSS-REFERENCE TO RELATED APPLICATION

This application claims benefit to U.S. Ser. No. 61/326,814 (APPM/015267L), filed Apr. 22, 2010, which is herein incorporated by reference in its entirety.

### BACKGROUND OF THE INVENTION

### 1. Field of the Invention

Embodiments of the invention generally relate to apparatuses and methods for induction heating of substrates.

### 2. Description of the Related Art

Group III-V materials are finding greater importance in the development and fabrication of a variety of semiconductor devices, such as short wavelength light-emitting diodes (LEDs), laser diodes (LDs), and electronic devices including high power, high frequency, high temperature transistors and integrated circuits. For example, short wavelength (e.g., blue/green to ultraviolet) LEDs are fabricated using the Group III-nitride semiconducting material gallium nitride (GaN), which is a Group III-V material. Short wavelength LEDs fabricated using GaN can provide significantly greater efficiencies and longer operating lifetimes than short wavelength LEDs fabricated using non-nitride semiconducting materials containing Group II-VI elements.

One method that has been used for depositing Group III-nitrides, such as GaN, is metal organic chemical vapor deposition (MOCVD). Generally, the MOCVD process is performed in a chamber/reactor having a temperature controlled environment to assure the stability of a first precursor gas which contains at least one Group III element, such as gallium. A second precursor gas, such as ammonia (NH₃), may be utilized to provide the nitrogen needed to form a Group III-nitride. The two precursor gases are injected into a processing zone within the chamber, mixed, and flowed towards and exposed to a heated substrate in the processing zone. A carrier gas may be used to assist in the transport of the precursor gases towards the substrate. The mixture of precursor gas reacts at the surface of the heated substrate to form a Group III-nitride layer, such as GaN, on the substrate surface.

Hydride vapor phase epitaxy (HVPE) is another process that has been used to form Group III-nitride materials. Most of the HVPE processes for growing Group III-V materials are generally performed in a reactor/chamber having a temperature controlled environment to assure the stability of a Group III metal used in the process. Group III metals provided by a Group III source, such as a gallium metal source, in the chamber reacts with a halide, such as hydrogen chloride (HCI) gas to form a Group III halide vapor, such as gallium chloride (GaCI₃). A nitrogen precursor gas, such as ammonia, is subsequently transported by a separate gas line to a reaction zone in the chamber, heated, and mixed with the Group III halide vapor. A carrier gas is often utilized to transport the Group III halide vapor and the nitrogen precursor gas towards the substrate within the chamber. The mixture of the Group III halide vapor and the nitrogen precursor gas, upon being exposed to the heated substrate, react while epitaxially growing a Group III-V layer (e.g., GaN) on the substrate surface.

As the demand for LEDs, LDs, transistors, and integrated circuits increases, the efficiency of depositing high quality Group-III nitride materials takes on greater importance. Therefore, there is a need for improved methods and apparatus for depositing high quality films onto substrates.

### SUMMARY OF THE INVENTION

Embodiments of the invention generally relate to processing chambers and methods for utilizing a plurality of induction heat sources to uniformly heat a plurality of substrates within the processing chambers. By utilizing multiple heating zones that are each separately powered, the temperature distribution across the susceptor, over which the substrates rotate, may be uniform. The heat sources may be disposed outside of the processing chamber at a predetermined distance from the susceptor.

In one embodiment, a processing chamber is provided and includes a chamber body having an electromagnetically transparent window, a gas distribution showerhead coupled with the chamber body, and a susceptor disposed within the chamber body opposite the gas distribution showerhead at a location adjacent the electromagnetically transparent window. The apparatus also includes a substrate carrier coupled with the susceptor and facing the gas distribution showerhead, a first inductive heating element disposed outside the chamber body adjacent the electromagnetically transparent window, and a second inductive heating element separate from the first inductive heating element and disposed outside the chamber body adjacent to the electromagnetically transparent window.

In another embodiment, a processing chamber is provided which includes a susceptor disposed adjacent a first side of an electromagnetically transparent window, a substrate carrier coupled with the susceptor, an inner inductive heating element disposed adjacent a second side of the electromagnetically transparent window opposite the first side, an outer inductive heating element separate from and encompassing the inner inductive heating element and disposed adjacent to the second side of the electromagnetically transparent window, and a parasitic load ring positioned below the outer inductive heating element and radially extending outside the perimeter of the outer inductive heating element, wherein the outer inductive heating element is disposed between the parasitic load ring and the electromagnetically transparent window.

In another embodiment, a method is provided and includes rotating a substrate carrier within a chamber body having an electromagnetically transparent window and applying power to a first heating element from a first power source at a first power level. The first heating element is disposed adjacent the electromagnetically transparent window and outside of the chamber body. The method also includes applying power to a second heating element that is separate from the first heating element and is disposed adjacent the electromagnetically transparent window outside of the chamber body. The power is applied from a second power source that is separate from the first power source, and the power is applied at a second power level that is different from the first power level.

In some embodiments, a parasitic load ring may be disposed below the outer inductive heating element, such that the outer inductive heating element is between the parasitic load ring and the electromagnetically transparent window. The method may further include positioning a parasitic load ring below the outer inductive heating element, heating the substrate carrier and the substrates, and maintaining a process temperature of the substrates with a substantially uniform temperature profile. Additionally, the method may further include adjusting a parasitic load applied to the outer edge of the outer inductive heating element while vertically traversing the parasitic load ring towards or away from the outer inductive heating element.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic cross-sectional view of a processing chamber according to embodiments described herein.

FIG. 1B is an isometric view of the susceptor of FIG. 1A.

FIG. 2 is a schematic cross-sectional view of another processing chamber according to other embodiments described herein.

FIG. 3 is a schematic illustration of a substrate carrier according to embodiments described herein.

To facilitate understanding, identical reference numerals have been used, where possible, to designate identical elements that are common to the figures. Elements and features of one embodiment may be beneficially incorporated in other embodiments without further recitation.

### DETAILED DESCRIPTION

Embodiments of the invention generally relate to apparatuses and methods for utilizing a plurality of induction heat sources to uniformly heat a plurality of substrates within a processing chamber. By utilizing multiple heating zones that are each separately powered, the temperature distribution across a susceptor and a substrate carrier, over which the substrates rotate, may be uniform. The heat sources may be disposed outside of the processing chamber. In one embodiment, a processing chamber is provided which includes a susceptor disposed adjacent a first side of a window, a substrate carrier coupled with the susceptor, an inner inductive heating element disposed adjacent a second side of the window opposite the first side, an outer inductive heating element separate from and encompassing the inner inductive heating element and disposed adjacent to the second side of the window, and a parasitic load ring positioned below the outer inductive heating element. The embodiments discussed herein may be performed utilizing a hydride vapor phase epitaxy (HVPE) apparatus or a metal organic chemical vapor deposition (MOCVD) apparatus, commercially available from Applied Materials, Inc., Santa Clara, CA or other manufacturers.

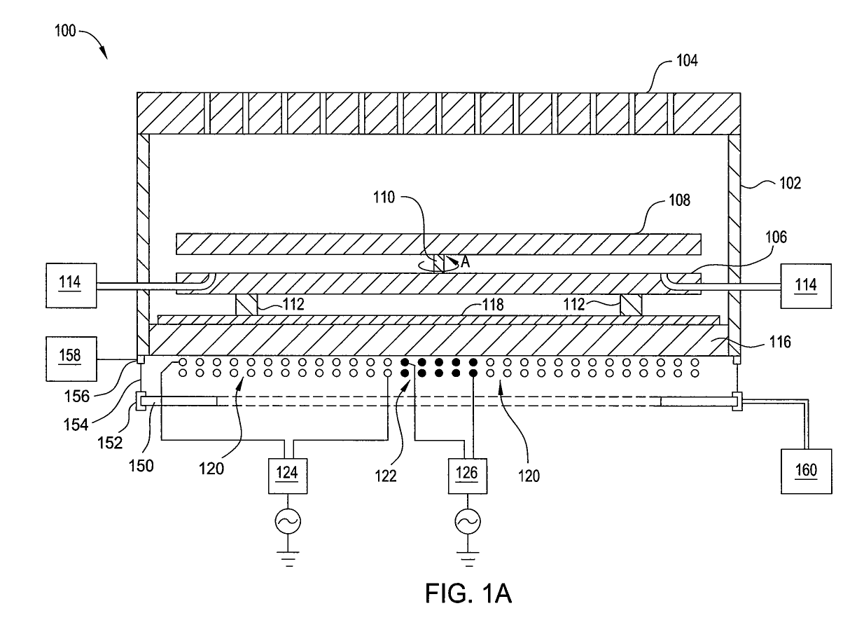

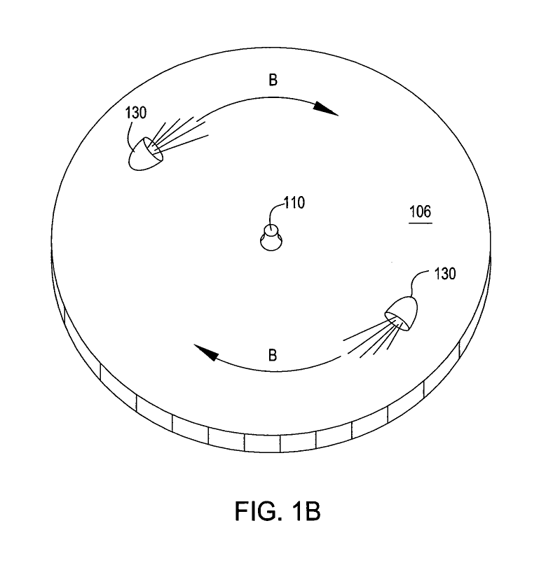

FIG. 1A is a schematic cross-sectional view of a processing chamber 100 according to one embodiment. The processing chamber 100 may be a deposition chamber or reactor and contains a multi-zone induction heating configuration that enables highly efficient and uniform heating of the susceptor 106 to elevated temperatures for epitaxial film growth. The multi-zone induction heating configuration enables tuning of the temperature uniformity to accommodate various heat loss scenarios inside the processing chamber 100. In the embodiment shown in FIG. 1A, the multi-zone induction heating configuration enables uniform heating of a flat susceptor, a carrier, or other flat workpiece.

The processing chamber 100 includes a chamber body 102 and a showerhead 104 for introducing the deposition gases. The susceptor 106 is disposed within the chamber body 102 opposite the showerhead 104. The bottom of the chamber body 102 has a window 116. In various configurations, the window 116 may be optically transparent, may contain a dielectric material that is electromagnetically transparent, or may be a metallic window with slits to reduce eddy currents. In general, the chamber body 102 may contain or be made of quartz, or alternatively, a metal, such as steel, stainless steel, aluminum, or alloys thereof. The quartz for the chamber body 102 is generally transparent, but alternatively, may be opaque. The susceptor 106 has a substantially flat bottom surface and is spaced from the window 116 by one or more spacers 112. The substrate carrier 108 may contain silicon carbide, graphite, graphite coated with silicon carbide, silicon carbide coated with graphite, or combinations thereof. In one example, the substrate carrier 108 may contain or be made of graphite. In another example, the substrate carrier 108 may contain or be made of graphite coated with silicon carbide. Due to the nature of induction heating, the susceptor 106 and substrate carrier 108 may have a variety of sizes. In one example, the substrate carrier 108 may have a thickness of between about 2.5 mm and about 4 mm and a diameter of between about 300 mm and about 375 mm. In another example, the substrate carrier 108 may have a thickness of between about 6 mm and about 9 mm and a diameter of between about 300 mm and about 375 mm. The susceptor 106 has a pin 110 thereon for positioning the substrate carrier 108. The substrate carrier 108 may be balanced or otherwise positioned on the pin 110 while rotating as shown by arrow “A”. In one example, the pin 110 may have a diameter of between about 1 mm and about 2 mm. In another example, the pin 110 may extend above the susceptor 106 by a distance of between about 2 mm and about 3 mm. The substrate carrier 108 rotates by introducing a gas through the susceptor 106.

Substrates that may be processed in the apparatus described herein, such as processing chamber 100, include, but are not limited to sapphire or other forms of aluminum oxides (e.g., Al₂O₃), silicon, silicon carbides (e.g., SiC), lithium aluminum oxides (e.g., LiAIO₂), lithium gallium oxides (e.g., LiGaO₂), zinc oxides (e.g., ZnO), gallium nitrides (e.g., GaN), aluminum nitrides (e.g., AIN), quartz, glass, gallium arsenides (e.g., GaAs), spinel (MgAl₂O₄), derivatives thereof, or combinations thereof. Any well know method, such as masking and etching may be utilized to form features, such as the posts, from a planar substrate to create a patterned substrate. The term substrate as used herein includes both patterned and non-patterned substrates and/or wafer.

FIG. 1B is an isometric view of the susceptor 106. The susceptor 106, as shown, has two nozzles 130 that are spaced at an angle of about 180° apart on the substantially circular shaped susceptor 106. The nozzles 130 face opposite directions so that the gas that flows out of the nozzles 130 will cause the substrate carrier 108 to rotate in the direction shown by arrows “B”. A clockwise rotation is illustrated in FIG. 1B, however, the gas nozzles 130 may be oriented to cause rotation of the substrate carrier 108 in the counterclockwise direction. In one example, as depicted, two nozzles 130 may be disposed on the susceptor 106. In other examples, three or more nozzles 130 may be disposed on the susceptor 106 (not shown). The substrate carrier 108 may rotate while balanced or otherwise disposed on the pin 110. The gas that is introduced through the nozzles 130 may contain a substantially inert gas relative to the process performed within the chamber. The gas may contain a noble gas, such as argon, helium, or neon, or may contain nitrogen gas (N₂). The gases are supplied from one or more gas sources 114. The gas is injected through the susceptor 106 from the side and is released at an angle. The substrate carrier 108 is then rotated by the gas. The gas is introduced horizontally through the susceptor 106. The gas is not introduced vertically through the susceptor 106 since induction heating creates eddy currents on the bottom surface of the susceptor 106 and having sharp features will lead to hot spots that can induce thermal cracks.

In order to heat the substrates that are positioned or otherwise placed on the substrate carrier 108 while the substrate carrier 108 is rotating, two or more heating elements may be used. The induction heating coils or elements 120, 122 may be sized appropriately to match the diameter of the element to be heated. In the embodiment depicted in FIG. 1A, the processing chamber 100 contains an outer inductive heating element 120 and an inner inductive heating element 122. The outer inductive heating element 120 is coupled to a first power source and a first heating controller 124. The inner inductive heating element 122 is coupled to a second power source and a second heating controller 126. Both the first power source and the first heating controller 124 are separate and distinct from the second power source and the second heating controller 126. The inductive heating elements 120, 122 operate independently of each other so that collectively, a wide range of precise temperature tuning is possible throughout the process temperature range, including temperatures of greater than 1,100° C. The inductive heating elements 120, 122 may be spaced from the bottom of the susceptor 106 by a distance of between about 0.2 inches and about 0.8 inches.

In other embodiments, a parasitic load ring 150 may be coupled with the processing chamber 100 and utilized to uniformly control the temperature profiles of the susceptor 106 and the substrate carrier 108 disposed there above, as well as a plurality of substrates disposed on the substrate carrier 108, as depicted in FIG. 1A. The parasitic load ring 150 is positioned just below the coils of the outer inductive heating element 120 while radially extending outside of perimeter of the outer inductive heating element 120. In one example, the parasitic load ring 150 may be coupled with the processing chamber 100 by at least one support arm 154 in which the parasitic load ring 150 may vertically traverse and be positioned at various distances from the outer inductive heating element 120. At least one support 152 may be coupled between the parasitic load ring 150 and the support arm 154, and at least one rising and lowering mechanism 156 may be coupled between the processing chamber 100 and the support arm 154. The support 152 may be a single bracket or support ring or may be multiple brackets coupled with the parasitic load ring 150. The rising and lowering mechanism 156 may be coupled with or otherwise attached to the sides or the bottom of the chamber body 102 and/or the transparent window 116 outside of the processing chamber 100. Generally, the parasitic load ring 150 is electrically grounded.

The uniformity of the temperatures of the susceptor 106, the substrate carrier 108, and substrates may be controlled by the addition of the parasitic load ring 150 to the edge of the outer inductive heating element 120. The parasitic load may capacitively load down the edges of the outer inductive heating element 120, or may absorb some of the power through eddy currents at the edges of the outer inductive heating element 120. The proximity of the parasitic load ring 150 to the edge of the outer inductive heating element 120 provides an adjustable edge loss, and hence controls the temperature uniformities of the susceptor 106, the substrate carrier 108, and substrates while being heated by the outer inductive heating element 120. Therefore, during a calibration step, a desirable separation distance may be determined by adjusting a parasitic load applied to the outer edge of the outer inductive heating element 120 while vertically traversing the parasitic load ring 150 towards or away from the outer inductive heating element 120. During MOCVD, HVPE, or other deposition process, the susceptor 106, the substrate carrier 108, and at least one substrate, usually a plurality of substrates, may be heated while maintaining a process temperature of the substrate or substrates with a substantially uniform temperature profile. Generally, the process temperature may be within a range from about 400° C. to about 1,250° C., such as from about 550° C. to about 1,150° C.

The parasitic load ring 150 may be positioned at a predetermined separation distance from the outer inductive heating element 120. In some configurations, the predetermined distance may be within a range from about 2 mm to about 50 mm, such as from about 2 mm to about 25 mm or from about 25 mm to about 50 mm. In one embodiment, the separation distance is adjusted prior to starting a process and maintained through numerous repetitions of the same process. In another embodiment, the separation distance is adjusted and continuously optimized in real time throughout the process relative to the process temperature set-point.

The parasitic load ring 150 contains a highly electrically and thermally conductive material. The parasitic load ring 150 may contain or be formed of steel, stainless steel (e.g., 400 series stainless steel), iron, nickel, chromium, aluminum, copper, alloys thereof, or combinations thereof. The parasitic load ring 150 may have a variety of geometries relative to the shape and size of the coils in the outer inductive heating element 120. Since the inductive coil assembly containing both the outer inductive heating element 120 and the inner inductive heating element 122 generally has a substantially similar or larger diameter than the susceptor 106 or the substrate carrier 108, the parasitic load ring 150 generally has a larger outer diameter than the inductive coil assembly containing both the outer inductive heating element 120 and the inner inductive heating element 122.

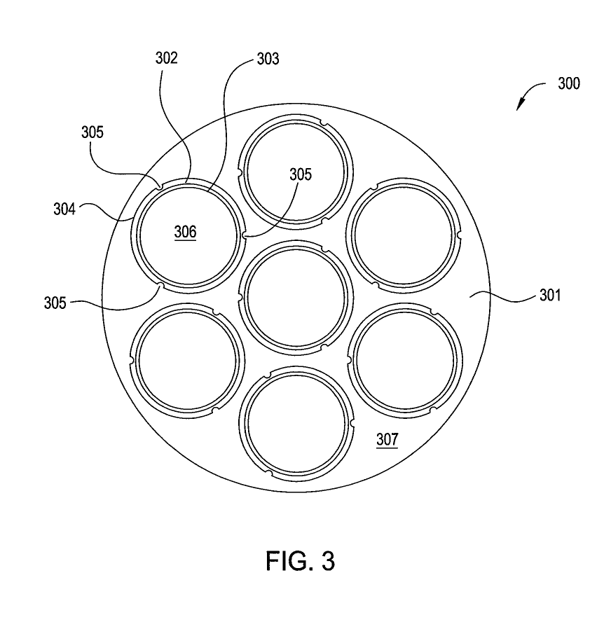

In one embodiment, the processing chamber 100 and the substrate carrier 108 is configured for multi-substrate processing—similar to the substrate carrier 300 depicted in FIG. 3—such that the substrate carrier 108 has a diameter of about 1,000 mm to about 1,500 mm, for example, about 1,200 mm, and each substrate may be a 300 mm round wafer. The parasitic load ring 150 may have an outer diameter within a range from about 1,300 mm to about 1,600 mm, such as from about 1,375 mm to about 1,550 mm, for example, about 1,450 mm; an inner diameter within a range from about 600 mm to about 1,200 mm, such as from about 800 mm to about 1,000 mm, for example, about 900 mm; a width measured between the inner and outer diameters within a range from about 80 mm to about 560 mm, such as from about 200 mm to about 360 mm, for example, about 280 mm; and a thickness within a range from about 1 mm to about 12 mm, such as from about 2 mm to about 6 mm, for example, about 4 mm.

In another embodiment, the processing chamber 100 and the substrate carrier 108 is configured for single substrate processing and may have a diameter of about 350 mm to about 500 mm, for example, about 400 mm, and each substrate may be a 300 mm round wafer. The parasitic load ring 150 may have an outer diameter within a range from about 320 mm to about 400 mm, such as from about 340 mm to about 380 mm, for example, about 360 mm; an inner diameter within a range from about 150 mm to about 300 mm, such as from about 200 mm to about 250 mm, for example, about 225 mm; a width measured between the inner and outer diameters within a range from about 20 mm to about 140 mm, such as from about 50 mm to about 90 mm, for example, about 70 mm; and a thickness within a range from about 1 mm to about 12 mm, such as from about 2 mm to about 6 mm, for example, about 4 mm.

In some embodiments, the rising and lowering mechanism 156 may be a screw-drive mechanism, the support arm 154 may have be a threaded bar, screw, or bolt, and support 152 contains a threaded hole for receiving the support arm 154. In some configurations, two, three, four, or more support arms 154 may be utilized to support the parasitic load ring 150 to the processing chamber 100 and for providing tracks for adjusting the proximity of the parasitic load ring 150 to the outer inductive heating element 120. A rising and lowering controller 158 may be utilized to ascend or descend the parasitic load ring 150 along the support arms 154. In other embodiments, the rising and lowering mechanism 156 may be a hydraulic mechanism, the support arm 154 may be piston or cylinder, and the support 152 receives the support arm 154.

In an alternative configuration, the support 152 and the rising and lowering mechanism 156 may be oppositely positioned—such that at least one support 152 may be coupled between the processing chamber 100 and the support arm 154, while at least one rising and lowering mechanism 156 may be coupled between the parasitic load ring 150 and the support arm 154. In another alternative configuration, the support 152 may be eliminated and the support arms 154 may be directly coupled to the parasitic load ring 150.

Also, a temperature control system 160 may be fluidly coupled with the parasitic load ring 150 and utilized to remove thermal energy away from the parasitic load ring 150. The temperature control system 160 may flow gas, such as forced air from a fan or a compressed air source, across the parasitic load ring 150. Also, the temperature control system 160 may circulate a liquid, a gas, a supercritical fluid, or combinations thereof between the parasitic load ring 150 and the temperature control system 160. In one example, a water chiller may be utilized as the temperature control system 160 while removing heat from the parasitic load ring 150.

In an HVPE process, at least three distinct processes may be performed during embodiments described herein. The first process that may occur is a nitridation process whereby one or more substrates is exposed to a nitrogen containing gas such as ammonia and nitrogen at a temperature range of between about 900° C. and about 1,000° C. Then, an amorphous aluminum nitride layer may be formed on the one or more substrates by introducing an aluminum precursor (such as aluminum chloride) and reacting the aluminum with nitrogen to form the amorphous aluminum nitride. The aluminum nitride may be formed at a temperature of between about 800° C. and about 900° C. In one embodiment, the aluminum nitride is formed at a temperature of between about 500° C. and about 950° C. A gallium nitride film may also be formed on the one or more substrates. The gallium nitride may be formed by introducing a gallium precursor (such as gallium chloride) and reacting the gallium precursor with nitrogen to form gallium nitride. The gallium nitride may be deposited at a temperature of between about 950° C. and about 1,100° C. In one embodiment, the gallium nitride may be formed at a temperature of between about 550° C. and about 1,150° C. In still another embodiment, the gallium nitride may be formed at a temperature of up to about 1,050° C.

In an MOCVD process, a layer, such as InGaN may be grown on one or more substrates using MOCVD precursor gases at a temperature of from about 750° C. to about 800° C. A p-GaN layer may be grown at a temperature of between about 850° C. and about 1,050° C. During formation of the p-GaN layer, the one or more substrates are heated at a temperature ramp-up rate of between about 5° C. per second to about 10° C. per second.

In one embodiment, the outer inductive heating element 120 may contain an induction coil that has between about 8 turns and about 11 turns. The outer inductive heating element 120 may be arranged in two substantially parallel rows and have an outer diameter of between about 12 inches and about 15 inches. The inner inductive heating element 122 may contain an induction coil that has between about 6 turns and about 9 turns. The inner inductive heating element 122 may be arranged in two substantially parallel rows and have an outer diameter of between about 3 inches and about 6 inches. Each of the heating element 120, 122 is not limited to size or the number of turns as those shown or described herein. For example, for heating a bigger substrate carrier 108 and susceptor 106, the size and shape of the inductive heating elements 120, 122 can be adjusted accordingly so the concept is not limited to the particular sizes discussed above. The outer heating element power supply and heating controller 124 may be arranged to supply and control power within a range from about 30 kW to about 45 kW while the inner heating element heating controller 126 and power supply may be configured to supply and control power within a range from about 10 kW to about 17 kW.

The inner inductive heating element 122 and the outer inductive heating element 120 are disposed outside of the chamber body 102 adjacent the transparent window 116. A coating 118 may be present on the transparent window to reflect heat back into the chamber. In one embodiment, the coating may contain gold, tungsten, titanium nitride, alloys thereof, derivatives thereof, or combinations thereof. In one example, the coating may contain titanium nitride. In another example, the coating 118 may contain gold or a gold alloy. In another example, the coating 118 may contain tungsten or a tungsten alloy, or any other reflective material that has high reflectivity in the infrared region. In one embodiment, the coating 118 may be present inside of the chamber body 102. In another embodiment, the coating 118 may be present outside of the chamber body 102. The coating may have a thickness of between about 0.5 pm and about 2.0 pm. The coating 118 permits the heat to enter the chamber body 102 with minimal reflectance back to the inductive heating elements 120, 122. The coating 118 also functions to reflect any heat within the chamber body 102 back into the chamber body 102 to minimize the amount of heat lost.

The inductive heating elements 120, 122 are advantageous because they are inductive heating elements rather than resistive heating elements. The inductive heating elements are more efficient than resistive heating elements because they utilize less energy and are powered by an RF power source. The inductive heating elements do not heat all of the surfaces and materials within the entire chamber, but rather, the energy is focused onto the predetermined material, such as contained within the substrate carrier 108 or susceptor 106.

During operation, processing gas is introduced through the showerhead 104 for processing the substrates that are contained within the substrate carrier 108. The substrate carrier 108 rotates upon the pin 110 while rotating/inert gas is introduced through the nozzles 130. Simultaneous with the rotation and gas introduction, both the inner inductive heating element 122 and the outer inductive heating element 120 is powered to inductively heat the susceptor 106 and hence, the substrates present on the substrate carrier 108. The power supplied to the inner inductive heating element 122 is less than the power supplied to the outer inductive heating element 120. The different power levels enable substantially uniform heating of the substrates during rotation. Additionally, the frequency of the power applied to the inner inductive heating element 122 and the outer inductive heating element 120 may be different. In one embodiment, the difference in frequency may be about 10%. In one embodiment, the spacing between the inductive heating elements 120, 122 and the bottom of the susceptor 106 is between about 0.1 inches to about 0.5 inches.

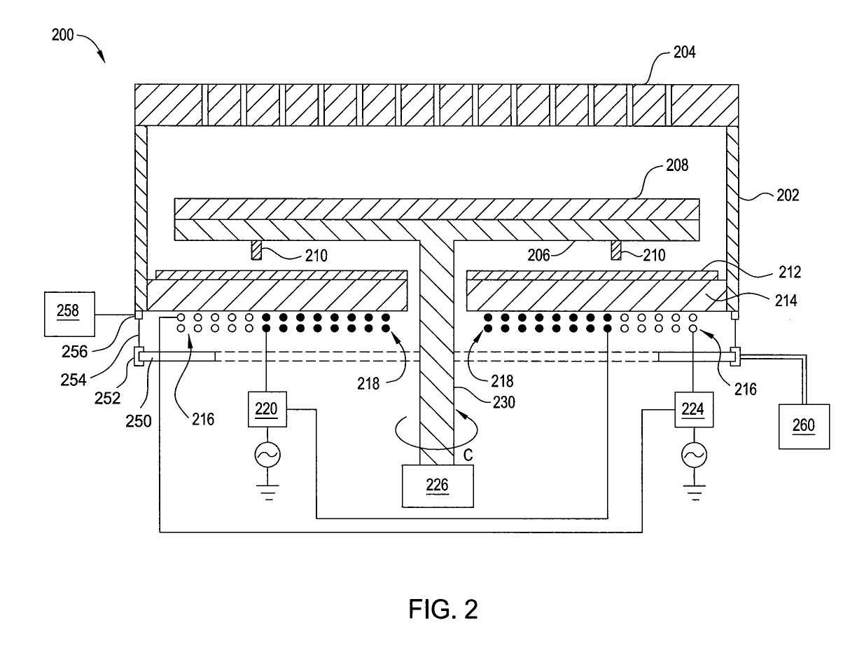

FIG. 2 is a schematic cross-sectional view of a processing chamber 200 according to another embodiment. In the embodiment shown in FIG. 2, uniform heating of a substrate carrier 206 on a susceptor 206 having a center stem and a large separation of the bottom wall of the processing chamber 200 is shown. The multi-zone induction heating enables a bigger separate distance between the induction coil and the workpiece. The separation walls attached to the bottom of the susceptor 206 prevents cross-talk between the two different power supplies while heating the substrate carrier 206 and/or the susceptor 206 inductively in similar resonating frequencies. A helical coil may be used to heat the stem from the inside while the induction coils outside of the chamber heat the remainder of the susceptor and/of the substrate carrier 206.

The processing chamber 200 includes a chamber body 202 and a gas distribution showerhead 204 for introducing processing gases. A susceptor 206 is disposed within the chamber body 202 with a substrate carrier 208 resting thereon. The susceptor 206 and hence, the substrate carrier 208, rotate during processing. The susceptor 206 has a stem 230 extending therefrom in a direction away from the substrate carrier 208. The stem 230 is coupled to a rotation mechanism 226 configured to impart rotational movement to the stem 230 and hence the susceptor 208 as shown by arrow “C”. Similar to the embodiment discussed above in FIG. 1A, a coating 212 may be present on the transparent window 214. The coating 212 may be present either within the chamber body 202 or outside of the chamber body 202. Also, the chamber body 202, the susceptor 206, and the substrate carrier 208 may contain materials similar to those discussed above in the embodiment illustrated by FIG. 1A.

To heat the susceptor 206 and hence, the substrates carried in the substrate carrier 208, inductive heat is provided by the inner heating element 218 that is powered by inner heating elements power sources and inner heating controller 220. Also, outer heating element 216 operates to inductively heat the substrates when the outer heating element 216 is powered by outer heating source and outer heating controller 224. The demarcation between the inner and outer inductive heating elements 216, 218 is defined by pins 210 that extend downward from the susceptor 206. The area from the pins 210 to the edge of the susceptor 206 is heated by the outer inductive heating element 216 while the area between the pins 210 and the stem 230 is heated by the inner heating elements 218. The stem 230 may be heated by an internal heating element. Collectively, the heating element within the stem 230, the inner inductive heating element 218, and the outer inductive heating element 216 function to provide a uniform temperature on the susceptor 206 and hence, the substrates carried by the substrate carrier 208. The pins 210 also function to prevent or reduce interference between the power supplies if the power supplies operate at similar frequencies. In one embodiment, the spacing between the inductive heating elements 216, 218 and the bottom of the susceptor 206 is between about 0.1 inches to about 1.0 inches.

In other embodiments, a parasitic load ring 250 may be coupled with the processing chamber 200 and utilized to uniformly control the temperature profiles of the susceptor 206 and the substrate carrier 208 disposed there above, as well as a plurality of substrates disposed on the substrate carrier 208, as depicted in FIG. 2. The parasitic load ring 250 is positioned just below the coils of the outer inductive heating element 216 while radially extending outside of perimeter of the outer inductive heating element 216. In one embodiment, the parasitic load ring 250 may be coupled with the processing chamber 200 by at least one support arm 254 in which the parasitic load ring 250 may vertically traverse and be positioned at various distances from the outer inductive heating element 216. At least one support 252 may be coupled between the parasitic load ring 250 and the support arm 254, and at least one rising and lowering mechanism 256 may be coupled between the processing chamber 200 and the support arm 254. The support 252 may be a single bracket or support ring or may be multiple brackets coupled with the parasitic load ring 250. The rising and lowering mechanism 256 may be coupled with or otherwise attached to the sides or the bottom of the chamber body 102 and/or the transparent window 214 outside of the processing chamber 200. Generally, the parasitic load ring 250 may be electrically grounded.

The uniformity of the temperatures of the susceptor 206, the substrate carrier 208, and substrates may be controlled by the addition of the parasitic load ring 250 to the edge of the outer inductive heating element 216. The parasitic load may capacitively load down the edges of the outer inductive heating element 216, or may absorb some of the power through eddy currents at the edges of the outer inductive heating element 216. The proximity of the parasitic load ring 250 to the edge of the outer inductive heating element 216 provides an adjustable edge loss, and hence controls the temperature uniformities of the susceptor 206, the substrate carrier 208, and the substrates while being heated by the outer inductive heating element 216. Therefore, during a calibration step, a desirable separation distance may be determined by adjusting a parasitic load applied to the outer edge of the outer inductive heating element 216 while vertically traversing the parasitic load ring 250 towards or away from the outer inductive heating element 216. During MOCVD, HVPE, or other deposition process, the susceptor 206, the substrate carrier 208, and at least one substrate may be heated while maintaining a process temperature of the substrate or substrates with a substantially uniform temperature profile. Generally, the process temperature may be within a range from about 400° C. to about 1,250° C., such as from about 550° C. to about 1,150° C.

The parasitic load ring 250 is positioned a predetermined distance from the outer inductive heating element 216. In some configurations, the predetermined distance may be within a range from about 2 mm to about 50 mm, such as from about 2 mm to about 25 mm or from about 25 mm to about 50 mm. In some configurations, the predetermined distance may be within a range from about 2 mm to about 50 mm, such as from about 2 mm to about 25 mm or from about 25 mm to about 50 mm. In one embodiment, the separation distance is adjusted prior to starting a process and maintained through numerous repetitions of the same process. In another embodiment, the separation distance is adjusted and continuously optimized in real time throughout the process relative to the process temperature set-point.

The parasitic load ring 250 may contain or be formed of steel, stainless steel (e.g., 400 series stainless steel), iron, nickel, chromium, aluminum, copper, alloys thereof, or combinations thereof. The parasitic load ring 250 may have a variety of geometries relative to the shape and size of the coils in the outer inductive heating element 216. Since the inductive coil assembly containing both the outer inductive heating element 216 and the inner inductive heating element 218 generally has a substantially similar or larger diameter than the susceptor 206 or the substrate carrier 208, the parasitic load ring 250 generally has a larger outer diameter than the inductive coil assembly containing both the outer inductive heating element 216 and the inner inductive heating element 218.

In one embodiment, the processing chamber 200 and the substrate carrier 208 is configured for multi-substrate processing—similar to the substrate carrier 300 depicted in FIG. 3—such that the substrate carrier 208 has a diameter of about 1,000 mm to about 1,500 mm, for example, about 1,200 mm, and each substrate may be a 300 mm round wafer. The parasitic load ring 250 may have an outer diameter within a range from about 1,300 mm to about 1,600 mm, such as from about 1,375 mm to about 1,550 mm, for example, about 1,450 mm; an inner diameter within a range from about 600 mm to about 1,200 mm, such as from about 800 mm to about 1,000 mm, for example, about 900 mm; a width measured between the inner and outer diameters within a range from about 80 mm to about 560 mm, such as from about 200 mm to about 360 mm, for example, about 280 mm; and a thickness within a range from about 1 mm to about 12 mm, such as from about 2 mm to about 6 mm, for example, about 4 mm.

In another embodiment, the processing chamber 200 and the substrate carrier 208 is configured for single substrate processing and may have a diameter of about 350 mm to about 500 mm, for example, about 400 mm, and each substrate may be a 300 mm round wafer. The parasitic load ring 250 may have an outer diameter within a range from about 320 mm to about 400 mm, such as from about 340 mm to about 380 mm, for example, about 360 mm; an inner diameter within a range from about 150 mm to about 300 mm, such as from about 200 mm to about 250 mm, for example, about 225 mm; a width measured between the inner and outer diameters within a range from about 20 mm to about 140 mm, such as from about 50 mm to about 90 mm, for example, about 70 mm; and a thickness within a range from about 1 mm to about 12 mm, such as from about 2 mm to about 6 mm, for example, about 4 mm.

In some embodiments, the rising and lowering mechanism 256 may be a screw-drive mechanism, the support arm 254 may have be a threaded bar, screw, or bolt, and support 252 contains a threaded hole for receiving the support arm 254. In some configurations, two, three, four, or more support arms 254 may be utilized to support the parasitic load ring 250 to the processing chamber 200 and for providing tracks for adjusting the proximity of the parasitic load ring 250 to the outer inductive heating element 216. A rising and lowering controller 258 may be utilized to ascend or descend the parasitic load ring 250 along the support arms 254. In other embodiments, the rising and lowering mechanism 256 may be a hydraulic mechanism, the support arm 254 may be piston or cylinder, and the support 252 receives the support arm 254.

In an alternative configuration, the support 252 and the rising and lowering mechanism 256 may be oppositely positioned—such that at least one support 252 may be coupled between the processing chamber 200 and the support arm 254, while at least one rising and lowering mechanism 256 may be coupled between the parasitic load ring 250 and the support arm 254. In another alternative configuration, the support 252 may be eliminated and the support arms 254 may be directly coupled to the parasitic load ring 250.

Also, a temperature control system 260 may be fluidly coupled with the parasitic load ring 250 and utilized to remove thermal energy away from the parasitic load ring 250. The temperature control system 260 may flow gas, such as forced air from a fan or a compressed air source, across the parasitic load ring 250. Also, the temperature control system 260 may circulate a liquid, a gas, a supercritical fluid, or combinations thereof between the parasitic load ring 250 and the temperature control system 260. In one example, a water chiller may be utilized as the temperature control system 260 while removing heat from the parasitic load ring 250.

FIG. 3 is a schematic illustration of a substrate carrier 300 according to one embodiment. The substrate carrier 300 generally contains a body 301 configured to provide structural support to one or more substrates thereon. In one embodiment, the body 301 may have a substantially disk shape. The body 301 may contain a material which has similar thermal properties, such as similar thermal expansion, with as the substrates to avoid unnecessary relative motion between the body 301 and the substrates. In one example, the body 301 contains silicon carbide. In one embodiment, the body 301 may contain or be formed of solid silicon carbide. In another embodiment, the body 301 is coated with a layer of silicon carbide by a chemical vapor deposition process. The body 301 may have a core containing graphite and a silicon carbide coating, such as a CVD coating.

In one embodiment, the body 301 has a plurality of pockets 302 formed on a top surface 307 of the body. Each pocket 302 is configured to retain one substrate therein. The plurality of pockets 302 may be distributed on the body 301 to effectively use surface areas of the body 301. In one embodiment, the surface pockets 302 are distributed in a circular manner as shown in FIG. 3.

The pockets 302 are generally recesses formed in the body 301. Each pocket 302 has sidewalls 304 and a bottom surface 306 defining a recess. The sidewalls 304 define an area slightly larger than the substrate so that an edge of the substrate is not in contact with the sidewalls 304. In one embodiment, the inner diameter of each pocket 302 may be larger than a diameter of the substrate being supported for up to about 0.05 inch.

In one embodiment, a raised ring 303 extending from the bottom surface 306 provides a supporting surface for supporting the substrate on a bottom surface of the substrate. In one embodiment, a plurality of stops 305 extending inward from the sidewalls 304 into the pocket 302. The stops 305 are configured to constrain the substrate from moving laterally. In one embodiment, the tip of the stops 305 form a circle with a diameter between about 3.94 inch to about 3.99 inch.

By utilizing two separate inductive heating sources that are separately powered, the temperature uniformity within an HVPE or MOCVD apparatus may be obtained. By increasing temperature uniformity, the deposition upon each substrate within the processing chamber may be substantially identical so that multiple substrates may be simultaneously processed.

While the foregoing is directed to embodiments of the invention, other and further embodiments of the invention may be devised without departing from the basic scope thereof, and the scope thereof is determined by the claims that follow.

1. A processing chamber, comprising:
a susceptor disposed adjacent a first side of an electromagnetically transparent window;
a substrate carrier coupled with the susceptor;
an inner inductive heating element disposed adjacent a second side of the electromagnetically transparent window opposite the first side; and
an outer inductive heating element separate from and encompassing the inner inductive heating element and disposed adjacent to the second side of the electromagnetically transparent window.

2. The processing chamber of claim 1, wherein the substrate carrier comprises silicon carbide, graphite, graphite coated with silicon carbide, or combinations thereof.

3. The processing chamber of claim 1, further comprising:
a first power supply coupled to the inner inductive heating element; and
a second power supply coupled to the outer inductive heating element, wherein the first power supply and the second power supply are configured to operate at different power levels and different frequencies.

4. The processing chamber of claim 1, wherein the susceptor further comprises a pin extending from a surface of the susceptor and the substrate carrier is in contact with the pin.

5. The processing chamber of claim 1, further comprising a coating on the electromagnetically transparent window and the coating comprises a material selected from the group consisting of gold, tungsten, titanium nitride, alloys thereof, and derivatives thereof.

6. The processing chamber of claim 1, wherein the susceptor has a stem extending outside of the chamber body and the susceptor is rotatable.

7. The processing chamber of claim 1, wherein the substrate carrier is rotatable relative to the susceptor.

8. The processing chamber of claim 1, further comprising a parasitic load ring positioned below the outer inductive heating element.

9. A processing chamber, comprising:
a susceptor disposed adjacent a first side of an electromagnetically transparent window;
a substrate carrier coupled with the susceptor;
an inner inductive heating element disposed adjacent a second side of the electromagnetically transparent window opposite the first side;
an outer inductive heating element separate from and encompassing the inner inductive heating element and disposed adjacent to the second side of the electromagnetically transparent window; and
a parasitic load ring positioned below the outer inductive heating element and radially extending outside the perimeter of the outer inductive heating element, wherein the outer inductive heating element is disposed between the parasitic load ring and the electromagnetically transparent window.

10. A method for heating at least one substrate, comprising:
rotating a substrate carrier containing at least one substrate adjacent a first side of an electromagnetically transparent window;
applying power to an inner inductive heating element from a first power source at a first power level, the inner inductive heating element disposed adjacent a second side of the electromagnetically transparent window opposite the first side;
applying power to an outer inductive heating element that is separate from the inner inductive heating element and is disposed adjacent the second side of the electromagnetically transparent window, the power applied from a second power source that is separate from the first power source, the power applied at a second power level that is different from the first power level, wherein a parasitic load ring is positioned below the outer inductive heating element; and
heating the substrate carrier and the substrate while maintaining a process temperature of the substrate with a substantially uniform temperature profile.

11. The method of claim 10, wherein the second power level is less than the first power level and the outer inductive heating element is disposed closer to the center of the substrate carrier than the inner inductive heating element.

12. The method of claim 11, wherein the substrate carrier is disposed over a susceptor and the substrate carrier rotates relative to the susceptor.

13. The method of claim 12, further comprising introducing a gas through the susceptor to cause rotation of the substrate carrier.

14. The method of claim 13, wherein the inner inductive heating element and the outer inductive heating element are each disposed less than about 0.5 inches from the susceptor.

15. The method of claim 14, wherein the inner inductive heating element and the outer inductive heating element remain stationary relative to the rotating substrate carrier.

16. The method of claim 10, wherein the substrate carrier comprises silicon carbide, graphite, graphite coated with silicon carbide, or combinations thereof.

17. The method of claim 10, wherein the process temperature is within a range from about 550° C. to about 1,150° C.

18. The method of claim 10, further comprising adjusting a parasitic load applied to the outer edge of the outer inductive heating element while vertically traversing the parasitic load ring towards or away from the outer inductive heating element.

19. The method of claim 10, wherein the parasitic load ring is positioned at a predetermined distance from the outer inductive heating element, the predetermined distance is within a range from about 2 mm to about 50 mm.

20. The method of claim 10, wherein the parasitic load ring comprises a material selected from the group consisting of steel, stainless steel, copper, and alloys thereof.
